(19) United States
(12) Patent Application Publication
(10) Pub. No.: US 2023/0343615 A1
(43) Pub. Date: Oct. 26, 2023

(54) IN-SITU LOW TEMPERATURE MEASUREMENT OF LOW EMISSIVITY SUBSTRATES

(71) Applicant: Applied Materials, Inc., Santa Clara, CA (US)

(72) Inventors: Prashant AGARWAL, Singapore (SG); Tuck Foong KOH, Singapore (SG); Ananthkrishna JUPUDI, Singapore (SG)

(21) Appl. No.: 17/726,808

(22) Filed: Apr. 22, 2022

(51) Int. Cl. H01L 21/67; H01L 21/673; H01L 21/687

(52) U.S. Cl. CPC H01L 21/67248; H01L 21/6732; H01L 21/68742

(57) ABSTRACT

A system for degassing substrates provides reduced infrared sources in a degas chamber. In some embodiments, the system includes a degas chamber with a microwave source and an infrared temperature sensor positioned in a bottom of the degas chamber, at least one hoop with an annular shape that is configured to support or lift a substrate and is formed from at least one first material that is opaque to microwaves and has an emissivity of 0.1 or less, and at least one actuator with a movable vertical shaft. Each of the at least one actuator is attached under one of the hoops at an outer perimeter of the hoop. The portion of the movable vertical shaft that is exposed to microwaves from the microwave source in the degas chamber is formed from at least one second material that is opaque to microwaves and has an emissivity of 0.1 or less.

### FIELD

Embodiments of the present principles generally relate to semiconductor processing of semiconductor substrates.

### BACKGROUND

During substrate processing such as degassing and the like, the temperature of the substrate being processed may be monitored. The temperature is then used to control the process which may include heating the substrate to certain temperatures at certain points within the process. Proportional-Integral-Derivative or PID controllers may be used to interpret the incoming substrate temperatures in order to adjust one or more parameters of the process to a particular setpoint. If the temperature information of the substrate is incorrect, the PID controller will be unaware and will incorrectly set parameters during the process, leading to substandard performance of the substrate during downstream processing. The inventors have observed that during processes in a degas chamber, the PID controllers routinely establish incorrect setpoints for degas process for low emissivity substrate materials, reducing performance of the process and, subsequently, the substrate performance during downstream processes.

Accordingly, the inventors have provided apparatus for ensuring correct low emissivity substrate in-situ temperature readings during processing.

### SUMMARY

Apparatus for improving in-situ low emissivity substrate temperature monitoring are provided herein.

In some embodiments, a system for degassing substrates may comprise a degas chamber with a microwave source and an infrared temperature sensor positioned in a bottom of the degas chamber, at least one hoop configured to support or lift a substrate wherein the at least one hoop has an annular shape and is formed from at least one first material that is opaque to microwaves and has an emissivity of 0.1 or less, and at least one actuator with a movable vertical shaft, wherein each of the at least one actuator is attached under one of the at least one hoop at an outer perimeter of the one of the at least one hoop wherein at least a portion of the movable vertical shaft exposed to microwaves from the microwave source in the degas chamber is formed from at least one second material that is opaque to microwaves and has an emissivity of 0.1 or less.

In some embodiments, the system may further include wherein the at least one first material comprises a first coating applied to the at least one hoop that is opaque to microwaves and has an emissivity of 0.1 or less, wherein the first coating is a silver-based material or an aluminum-based material on a core material of stainless steel, wherein the at least one second material comprises a second coating applied to at least the portion of the movable vertical shaft exposed to microwaves from the microwave source in the degas chamber and wherein the second coating is opaque to microwaves and has an emissivity of 0.1 or less, wherein the second coating is a silver-based material or an aluminum-based material on a core material of stainless steel and wherein the silver-based material or the aluminum-based material has an emissivity of 0.1 or less, wherein the movable vertical shaft comprises an upper portion of a third material that is opaque to microwaves and has an emissivity of 0.1 or less and a lower portion of a fourth material, wherein the movable vertical shaft is formed from an aluminum-based material that is opaque to microwaves and has an emissivity of 0.1 or less, a proportional-integral-derivative (PID) controller in communication with the infrared temperature sensor and the microwave source, wherein the PID controller is configured to control a processing temperature of the substrate based on a reading from the infrared temperature sensor and adjustment of the microwave source, wherein one of the at least one hoop is configured to support the substrate during processing in the degas chamber, and/or wherein one of the at least one hoop is configured to lift the substrate before and after processing in the degas chamber.

In some embodiments, an assembly for a degas chamber may comprise a movable vertical shaft configured to be installed in the degas chamber, wherein the movable vertical shaft has a bottom end configured to be attached to an actuator and a top end configured to be attached to a hoop that is configured to support or lift a substate, wherein an upper portion of the movable vertical shaft is exposed to an inner environment of the degas chamber when installed in the degas chamber, and wherein the movable vertical shaft is formed from at least one material that is opaque to microwaves and has an emissivity of 0.1 or less.

In some embodiments, the assembly may further include wherein the at least one material comprises a coating applied to at least the upper portion of the movable vertical shaft which is exposed to inner environment of the degas chamber when the movable vertical shaft is installed in the degas chamber and wherein the coating is opaque to microwaves and has an emissivity of 0.1 or less; wherein the coating is a silver-based material or an aluminum-based material on a core material of stainless steel and wherein the silver-based material or the aluminum-based material has an emissivity of 0.1 or less; wherein the movable vertical shaft comprises the upper portion and a lower portion, wherein the upper portion is removable from the lower portion, and wherein the upper portion formed is from material that is opaque to microwaves and has an emissivity of 0.1 or less and the lower portion is formed from stainless steel; wherein the upper portion and the lower portion are press-fit together, welded together, screwed together, or bolted together; and/or wherein the movable vertical shaft is formed from an aluminum-based material that is opaque to microwaves and has an emissivity of 0.1 or less.

In some embodiments, an assembly for a degas chamber may comprise a hoop configured to support or lift a substrate in the degas chamber, wherein the hoop has an annular shape with an area configured to attach to a movable shaft connected to an actuator, wherein the hoop is formed from at least one material that is opaque to microwaves and has an emissivity of 0.1 or less.

In some embodiments, the assembly may further include wherein the at least one material comprises a coating applied to an outer surface of the hoop, wherein the coating is opaque to microwaves and has an emissivity of 0.1 or less, wherein the coating is a silver-based material or an aluminum-based material on a core material of stainless steel, and/or wherein the hoop is configured to support a substrate during processing in the degas chamber or is configured to lift the substrate before and after processing in the degas chamber.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts graphs of a first run of substrates in an untreated degas chamber in accordance with some embodiments of the present principles.

FIG. 2 depicts graphs of a second run of substrates in a treated degas chamber in accordance with some embodiments of the present principles.

FIG. 3 depicts materials with high emissivity that are transparent to microwaves or absorb microwaves in accordance with some embodiments of the present principles.

FIG. 4 depicts materials with low emissivity that are opaque to microwaves in accordance with some embodiments of the present principles.

FIG. 5 depicts a degas chamber with high emissivity chamber assemblies in accordance with some embodiments of the present principles.

FIG. 6 depicts a degas chamber with low emissivity chamber assemblies including low emissivity hoops and low emissivity shaft material for an actuator assembly of a degas chamber in accordance with some embodiments of the present principles.

FIG. 7 depicts a degas chamber with low emissivity chamber assemblies including low emissivity hoops and a low emissivity two-piece shaft for an actuator assembly of a degas chamber in accordance with some embodiments of the present principles.

FIG. 8 depicts low emissivity shafts for an actuator assembly of a degas chamber in accordance with some embodiments of the present principles.

FIG. 9 depicts low emissivity hoops of a degas chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and apparatus provide a chamber environment that is conducive for determining in-situ substrate temperatures for substrate materials that have low emissivity at low temperatures (less than 200 degrees Celsius). Substrate low emissivity materials such as silicon are often ‘misread’ by infrared (IR) temperature sensors installed in chambers such as degas chambers. The false readings lead to improper control of the degas process by the PID controller. By reducing the emissivity of components within the degas chamber, a more accurate reading of the substrate is possible, dramatically increasing the quality control of the process and producing higher performance substrates in downstream processes.

Degas chambers have been used for drying and degassing of substrates in the industry using high temperatures (e.g., 500 degrees Celsius to 700 degrees Celsius, etc.). At high temperatures, substrate materials such as, for example, silicon exhibit higher emissivity characteristics. However, with the introduction of polymer materials as part of the semiconductor manufacturing, high temperatures will warp and damage the polymer materials. When the degas chambers are operated at low temperatures (less than 200 degrees Celsius), the emissivity of the substrate materials is altered, and in the case of silicon, becomes a low emissivity substrate material of 0.1 or less. The processing of polymer materials brought about low temperature degassing which presented the problem of reading substrate materials with low emissivity characteristics at the low temperatures. The inventors observed incomplete drying and/or degassing of the substrates at low temperatures. Increasing the degassing time for each substrate was unacceptable as the degassing process throughput would be dramatically reduced. As such, the inventors identified root causes and provided solutions to enable accurate IR temperature readings which subsequently produced degassing processes with higher quality and yields. The methods and apparatus disclosed herein provide solutions to low temperature IR readings of low emissivity materials and may be used in other types of chambers besides degassing chambers.

In the example using, but not limited to, the degas chamber, the inventors have found that the microwaves used for drying and degassing the substrates by heating the substrates will also heat the high emissivity chamber assemblies which then emit IR, effectively overwhelming the IR temperature sensor readings of the substrate. The IR temperature sensor begins to report a temperature of the heated chamber components rather than the temperature of the substrate to the process controllers. The process controllers then incorrectly alter the amount of microwave power required to reach the temperature setpoints. The inventors have found that as subsequent substrates are processed in the chamber, less heating of the substrate occurs because the degas chamber retains the heat in the high emissivity components. The incorrect readings lead to increased moisture/gas retention in the substrates which leads to delamination and other defects during subsequent substrate processing for plasma vapor deposition (PVD) metal films. The inventors have found that the IR sensor readings can be substantially improved by using chamber components that do not readily absorb microwave energy and emit the microwave energy through IR radiation.

The inventors have found that by creating a chamber with low emissivity assemblies of 0.1 or less at low temperatures, the low emissivity substrate materials can be accurately monitored. In the case of the degas chamber, the inventors have also found that a substantial improvement in accurate reporting of in-situ temperatures of the substrate can be made by specifically reducing the emissivity of the lifting and support hoop assemblies and the actuator shaft assemblies that control the movement of the hoops. The inventors have further found that low emissivity can be achieved by replacing the existing high emissivity material used to form the assemblies with low emissivity material. However, in some cases, the low emissivity material may not have the structural rigidity necessary to perform as assemblies made from higher emissivity materials. The inventors found that a low emissivity coating may be used over the high emissivity material of the assembly to form an assembly with high rigidity and also with low emissivity. The thickness of the low emissivity coating or plating is determined by the penetration depth or skin effect of the microwaves. The thickness is selected to be greater than the penetration depth or skin effect based on the microwave frequencies and coating material such that microwave energy is not absorbed and radiated as IR from the assembly (the coating or plating is thick enough to reflect or absorb the microwave energy before the energy can be transmitted and absorbed by the underlying material/materials).

In the example of the degas chamber, the IR temperature sensor is typically mounted on the bottom of a degas cavity and serves as the main or only substrate temperature monitoring sensor. The degas chamber contains at least one hoop assembly and actuator shaft assembly for supporting and transferring substrates. The inventors have found a substantial reduction in temperature reporting errors if the hoop assembly and actuator shaft assembly are made of a low emissivity material. With a low emissivity material, the substrate is heated but the hoop assembly and actuator shaft assembly produce negligible IR energy from the microwaves, reducing IR noise picked up by the IR temperature sensor. However, the lift hoop assembly needs to be structurally rigid to provide support without vibrating and may be coated or plated with a low emissivity material, such as silver or aluminum and the like, over a high emissivity material, such as stainless-steel and the like. The actuator shaft assembly can also be coated or plated with a low emissivity material over a high emissivity material such as stainless-steel and the like. The actuator shaft assembly may also be formed with an actuator shaft extension of low emissivity material such as aluminum and/or ceramics, and the like. The actuator shaft extension may include only the portion of the actuator shaft that is exposed to the chamber processing environment, allowing the remaining portion to be of a stronger and higher emissivity material such as stainless-steel and the like. The inventors have found that silver plating or aluminum plating over stainless steel provides a low emissivity assembly for low temperature, low emissivity material substrate processing. The inventors have also found that ceramics, polyetheretherketone (PEEK) material, and/or cross-linked polystyrene microwave stable materials may be used to form the chamber assemblies and/or used as a coating for stainless-steel assemblies and other structurally rigid materials. Rhodium may also be applied over silver coating/plating to prevent tarnishing of the silver coating/plating.

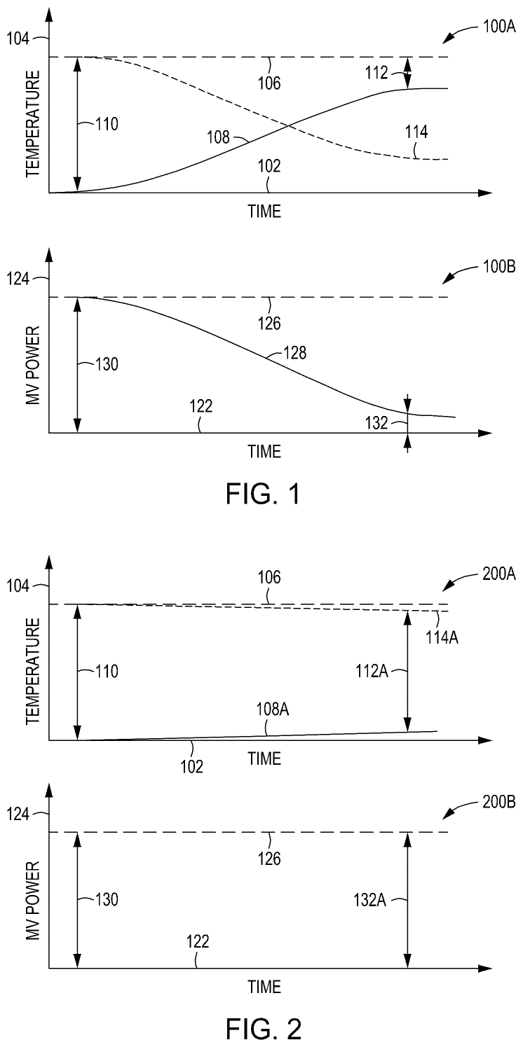

In FIG. 1 is a first graph 100A of time 102 versus temperature 104 and a second graph 100B of time 122 versus microwave power 124 for a first run of substrates in a degas chamber with assemblies not treated for reduced infrared transmissions. The inventors found that for the first few substrates, the actual substrate temperature 114 reached 110 the desired substrate temperature, allowing for quality degas operations to be performed. As additional substrates were processed, the idle temperature 108 read by the IR temperature sensor increased, causing a reduced difference 112 between the idle temperature 108 and the desired substrate temperature 106. As depicted in the second graph 1006, when the idle temperature 108 was low, the initial applied microwave power 130 for the initial substrates was high as indicated by the microwave power curve 128, meeting a desired power level 126 and raising the actual substrate temperature 114 to the desired substrate temperature 106. When the idle temperature 108 was high (reduced difference 112), the subsequent applied microwave power 132 was very low as indicated by the microwave power curve 128, resulting in poor degassing of the substrates, as the low applied power was not sufficient for the substrates to reach the desired substrate temperature 106 (actual substrate temperature 114 was much lower for later substrates in a run than the initial substrates).

The inventors found that the PID controller was using the idle temperature as a preheated substrate state and determining the microwave power needed to heat the substrate from the idle temperature 108 to the desired substrate temperature 106 (PID setpoint), resulting in underheated substrates (the substrates were actually at a much lower temperature, see, actual substrate temperature 114 of FIG. 1). The inventors further found that the microwaves were heating assemblies (e.g., supports, actuators, etc.) in the degas chamber along with the substrates during processing, causing the chamber assemblies to radiate IR that overshadowed the IR that the IR temperature sensor was attempting to read from the substrates. Although, at the initial start of the run, the chamber assemblies contributed little IR noise to the IR temperature sensor readings, after a few substrates were processed, the IR noise from the chamber assemblies increased to a level that mostly masked the IR emitted by the substrates. The problem was further exacerbated by the low emissivity of the substrate material (e.g., silicon at 0.1 emissivity) at low temperatures being read by the IR sensor (e.g., less than 200 degrees Celsius).

The inventors determined that hoops used to transport and support the substrates along with the shafts exposed to the chamber environment contributed the most emitted IR within the degas chamber assemblies. The inventors found that by reducing the emissivity of the particular chamber assemblies to at or below 0.1 emissivity, the idle temperature within the degas chamber was substantially reduced, resulting in substrates heated to desired temperatures and higher quality processing. In FIG. 2 is a third graph 200A of time 102 versus temperature 104 and a fourth graph 200B of time 122 versus microwave power 124 for a second run of substrates in the degas chamber with particular chamber assemblies treated for reduced infrared emissions. The inventors found that with the hoops and shafts treated for reduced IR emissions, the idle temperature 108A was substantially reduced, allowing the PID controller to correctly determine the needed microwave power to heat the substrates to the desired substrate temperature 106 (differences between the idle temperature 108A and no idle temperature are exaggerated in the third graph 200A so as to be more easily discernable and understood). The inventors found that the actual substrate temperatures 114A of the substrates of the second run substantially reached 112A the desired substrate temperature 106 as the idle temperature 108A was reduced to insignificant levels, allowing for quality degas operations to be performed, increasing degas processing yields (differences of the actual substrate temperature 114A and the desired substrate temperature 106 are exaggerated in the third graph 200A so as to be more easily discernable and understood). With the IR temperature sensor having the ability to correctly read the IR from the low emissivity material of the substrate, the PID controller was able to correctly apply power to the microwave source which in turn heated the substrate to the desired substrate temperature 106. After treatment, the second subsequent applied microwave power 132A was substantially the same as the initial applied microwave power 130, resulting in properly heated substrates throughout the second run of substrates.

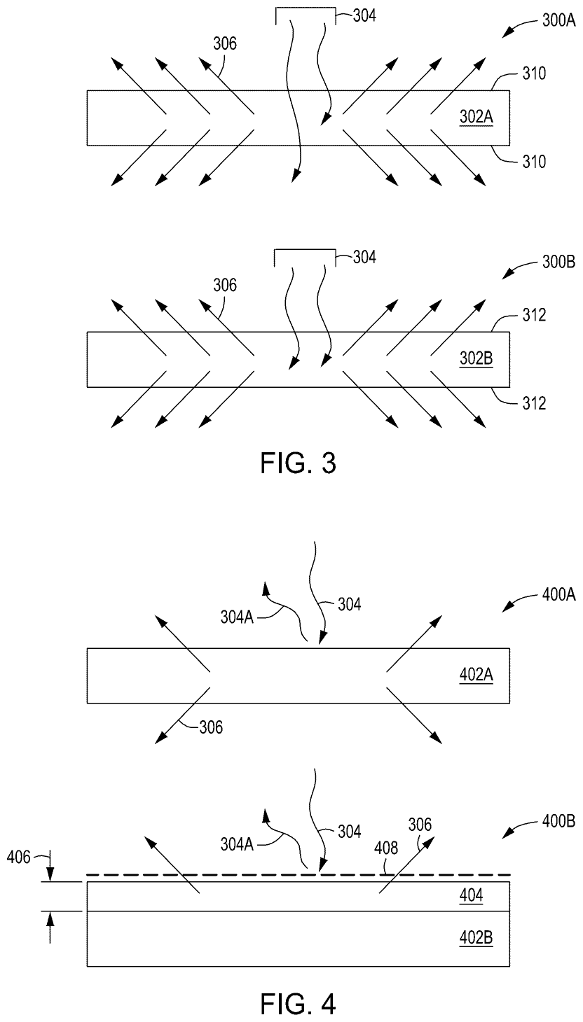

Microwaves, in general, may be transmitted (pass through a material), reflected (from a surface of a material), and/or absorbed (which may cause heating of the material). Although metal materials may reflect a substantial portion of microwaves, if the metal material is thin enough, the microwaves may also pass through the metal material. Thickness and type of material play a part in the amount of transmitted, reflected, and absorbed microwaves. In FIG. 3, a first view 300A depicts a first material 302A that transmits and absorbs microwaves 304. As the microwaves 304 pass through the first material 302A, some of the microwave energy is absorbed which heats the first material 302A, resulting in IR noise 306 being emitted from the exposed surfaces 310 of the first material 302A. In a second view 300B of FIG. 3, a second material 302B that is opaque to microwaves and absorbs microwaves 304 is depicted. As the microwaves 304 are absorbed into the second material 302B, the microwaves heat the second material 302B which results in IR noise 306 being emitted from the exposed surfaces 312 of the second material 302B. The inventors have found that the first material 302A that has microwave transparency and the second material 302B that absorbs microwaves are both problematic in that IR noise 306 is emitted from both types of materials and contribute to incorrect IR temperature sensor readings. The inventors found that a material that is opaque to microwaves and has a low emissivity of 0.1 or less provides the optimal material for reduction in emitted IR noise. In FIG. 4, a first view 400A depicts a third material 402A that is opaque to microwaves 304 (microwaves 304 are largely reflected 304A by the third material 402A) and has a low emissivity of IR noise 306 (emissivity of 0.1 or less). Types of materials that possess such characteristics may be, but are not limited to, silver, aluminum, ceramics, polyetheretherketone (PEEK), and/or cross-linked polystyrene microwave stable materials and the like. The lower the emissivity, the less emitted IR noise, and the more accurate the IR temperature sensor will read a substrate temperature.

Some of the materials, such as PEEK, silver, and polystyrene, while performing well at absorbing microwaves while emitting low IR noise levels, are not ideal for use as structural components due to the softness of the materials. The inventors have found, however, that the materials may still be used as coatings for materials used as structural components. In FIG. 4, a second view 400B depicts a structural material 402B, such as, but not limited to, stainless-steel material coated with a microwave opaque material 404 with low emissivity of 0.1 or less. By combining multiple types of materials, structural rigidity is maintained while IR noise emissions are reduced, allowing for more accurate IR temperature sensor readings. A thickness 406 of the microwave opaque material 404 or coating should be sufficient to prevent any skin depth effect from allowing microwaves to be transmitted through the material (different thicknesses may be needed for different microwave wavelengths used in a given chamber, etc.). In some embodiments, the coating may be applied via plating processes such as electroplating and the like (e.g., silver electroplating on stainless-steel, etc.). In some embodiments, an optional layer of rhodium 408 may be applied to a silver coating to prevent tarnishing on the outer surface of the silver coating.

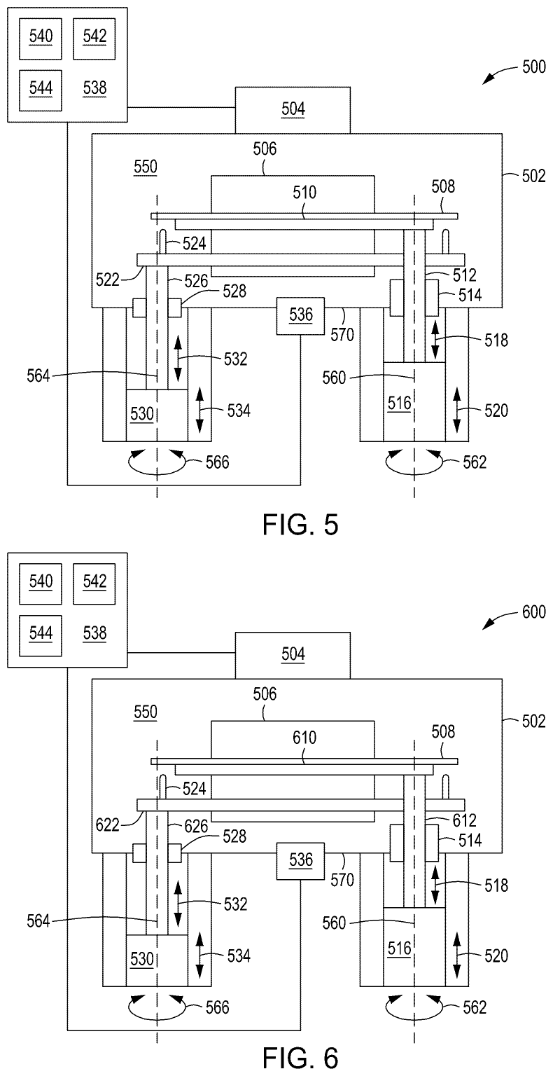

In a view 500 of FIG. 5, a degas chamber 502 with high emissivity chamber assemblies is depicted. The degas chamber 502 has a microwave source 504 with a wave guide opening 506 into a processing volume 550 of the degas chamber 502. In some embodiments, the degas chamber 502 may have a lifting hoop 522 with lifting pins 524 that is attached to a first actuator 530 via a first actuator shaft 526. The lifting hoop 522 lifts the substrate 508 and transports the substrate 508 in and out of the degas chamber 502. The first actuator shaft 526 passes through a first bellows 528 that flexes as the first actuator shaft 526 moves 532 to prevent the processing volume 550 from being exposed to the exterior environment. The first actuator shaft 526 moves 532 in response to the first actuator 530 movement 534. In some embodiments, the first actuator 530 and the first actuator shaft 526 may also rotate 566 about a center axis 564 of the first actuator shaft 526. In some embodiments, the degas chamber 502 may have a substrate support hoop 510 that is attached to a second actuator 516 via a second actuator shaft 512.

The substrate support hoop 510 supports the substrate 508 during degassing of the substrate 508. The second actuator shaft 512 passes through a second bellows 514 that flexes as the second actuator shaft 512 moves 518 to prevent the processing volume 550 from being exposed to the exterior environment. The second actuator shaft 512 moves 518 in response to the second actuator 516 movement 520. In some embodiments, the second actuator 516 and the second actuator shaft 512 may also rotate 562 about a center axis 560 of the second actuator shaft 512. An IR temperature sensor 536 is positioned in the bottom 570 of the degas chamber 502. The IR temperature sensor 536 reads the temperature of the substrate 508 based on radiated IR emitted from the substrate 508. A controller 538 with a central processing unit (CPU) 540, memory 542, and supporting circuits 544 may be configured to operate as a PID controller that interfaces with the IR temperature sensor 536 and the microwave source 504 to facilitate in adjusting the temperature of the substrate 508 during processing in the degas chamber 502.

The inventors have found that with low emissivity substrate materials of approximately 0.1 emissivity or less at low temperatures (approximately 200 degrees Celsius or less), the IR temperature sensor 536 was having difficulties determining the actual temperature of the substrate 508 due to other chamber assemblies within the processing volume 550 emitting IR noise stronger than IR emitted from the substrate 508. An initial substrate in a run of substrates may be processed correctly, but later substrates in the run did not reach a high enough temperature to be acceptably degassed due to the assemblies within the degas chamber 502 absorbing energy from the microwaves and emitting greater amounts of IR noise over time, increasing the idle temperature of the degas chamber 502 when no substrates were in the chamber. The high idle temperatures caused subsequent substrates to be degassed at low temperatures which produced poor quality degassing and performance issues in downstream processing (e.g., metal film delaminating).

Due to the positioning of the IR temperature sensor 536 at the bottom 570 of the degas chamber 502, the inventors found that a substantial amount of unwanted IR noise was being emitted by the first actuator shaft 526, the lifting hoop 522, the second actuator shaft 512, and the substrate support hoop 510. Stainless-steel material used to form the aforementioned chamber assemblies absorbed the microwaves during degas processing and, with a high emissivity of over 0.2, readily emitted IR noise inside of the processing volume 550 which was read by the IR temperature sensor 536, resulting in inaccurate substrate temperature readings. To reduce the unwanted IR noise inside the processing volume 550, the first actuator shaft 526 was replaced with a first low emissivity actuator shaft 626, the second actuator shaft 512 was replaced with a second low emissivity actuator shaft 612, the lifting hoop 522 was replaced with a low emissivity lifting hoop 622, and the substrate support hoop 510 was replaced with a low emissivity substrate support hoop 610 as depicted in a view 600 of FIG. 6.

When the chamber assemblies were replaced with a low emissivity (0.1 emissivity or less) assembly, the idle temperature of the degas chamber 502 dropped to insignificant levels, allowing highly accurate temperature readings of the substrate 508 by the IR temperature sensor 536. The accurate temperature readings reported by the IR temperature sensor 536 to the PID controller of the controller 538 allowed the PID controller to correctly control the required microwave power to the microwave source 504 which, in turn, heated the substrate 508 to the desired process temperature, increasing the degas process quality and yield. In some embodiments, the first low emissivity actuator shaft 626 and the second low emissivity actuator shaft 612 were formed from a low emissivity material such as aluminum and the like. The aluminum material is opaque to microwaves and has an emissivity of less than 0.1 while being structural rigid enough to meet the structural requirements of a functioning actuator shaft.

In some embodiments, the first low emissivity actuator shaft 626 and the second low emissivity actuator shaft 612 may be stainless-steel material that is coated or plated with a low emissivity material such as ceramics, aluminum, or silver and the like. The thickness of the coating or plating should be sufficient to account for skin effect of particular microwave wavelengths generated by the microwave source 504 into the degas chamber 502. Similarly, in some embodiments, the low emissivity lifting hoop 622 and the low emissivity substrate support hoop 610 may be formed from stainless-steel and coated or plated with a low emissivity material such as ceramic, aluminum, or silver and the like. The thickness of the coating or plating should be sufficient to account for skin effect of particular microwave wavelengths generated by the microwave source 504 into the degas chamber 502.

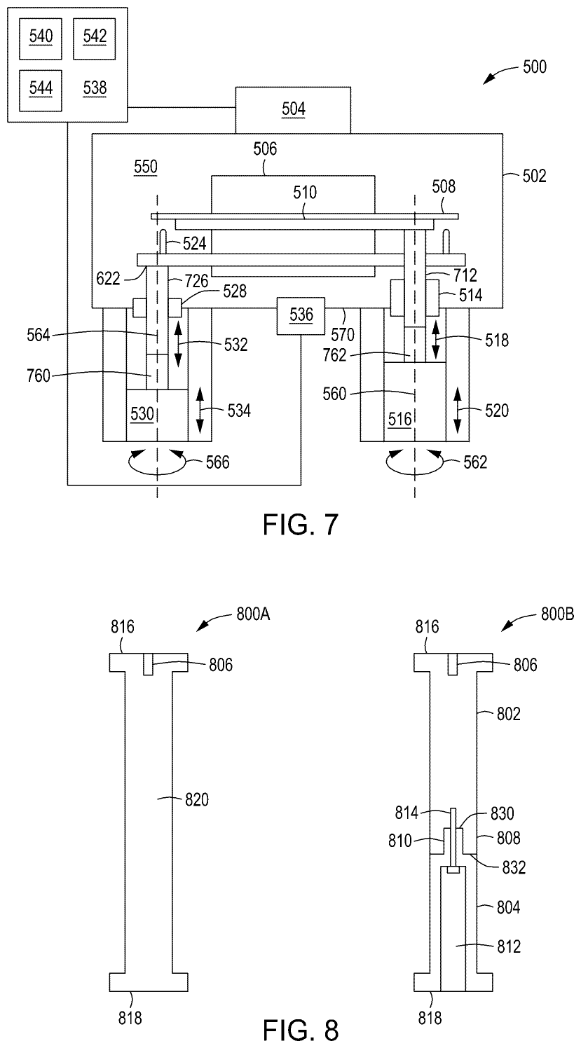

In some instances, the inventors have found that only the portion of the first actuator shaft 526 and the second actuator shaft 512 that is exposed to the processing volume 550 of the degas chamber 502 should be low emissivity. The remaining portion of the first actuator shaft 526 and the second actuator shaft 512 is never exposed to the processing volume 550 of the degas chamber 502 and whether the remaining portions are low emissivity or not had no bearing on the readings of the IR temperature sensor 536. In some embodiments, the first actuator shaft 526 and the second actuator shaft 512 may be replaced by two-piece actuator shafts such as a first low emissivity upper shaft extension 726 supported by a first lower shaft 760 and a second low emissivity upper shaft extension 712 supported by a second lower shaft 762 as depicted in a view 700 of FIG. 7. In some embodiments, the first low emissivity upper shaft extension 726 and the second low emissivity upper shaft extension 712 may be formed of a low emissivity (0.1 or less) material such as aluminum and the like while the first lower shaft 760 and the second lower shaft 762 may be formed from stainless-steel material and the like. In some embodiments, the first low emissivity upper shaft extension 726 and the second low emissivity upper shaft extension 712 may be formed from stainless-steel and coated or plated with a low emissivity (0.1 or less) material such as ceramic, aluminum, or silver and the like while the first lower shaft 760 and the second lower shaft 762 may be formed from uncoated stainless-steel material and the like.

FIG. 8 depicts low emissivity actuator shafts such as a low emissivity actuator shaft 820 in a view 800A and a two-piece actuator shaft 808 with a low emissivity upper shaft extension 802 with a lower shaft 804. In some embodiments, the low emissivity actuator shaft 820 has an upper flange or upper mating surface 816 that directly interfaces with a support area of a hoop such as the lifting hoop or substrate support hoop. At least one fastening hole 806, in some embodiments, may provide threads for a screw, bolt, or other fastener, threaded or unthreaded, to hold the hoop to the low emissivity actuator shaft. The at least one fastening hole 806, in some embodiments, may provide a press fit contact surface for a pin or other fastener to hold the hoop to the low emissivity actuator shaft 820. The low emissivity actuator shaft 820 has lower flange or lower mating surface 818 that directly interfaces with an actuator that provides movement to the low emissivity actuator shaft 820 which in turn provides movement to an attached hoop.

In some embodiments as depicted in the view 800B, similar upper and lower mating surfaces may be provided. The low emissivity upper shaft extension 802 may be formed with a recess 830 that mates with an extension or protrusion 810 formed on an upper end 832 of the lower shaft 804. The recess 830 and the protrusion 810 allow the low emissivity upper shaft extension 802 to directly interconnect with the lower shaft 804 either with a press fit or by using a connecting component 814 such as a screw or bolt and the like to hold the parts together. If a connecting component 814 is to be used, a lower recess 812 may be formed into the lower shaft 804 to allow access to insert the connecting component 814. If a press fit is used, the lower recess 812 and the connecting component 814 are not required. Similarly, if welding is used for connection, the lower recess 812 and the connecting component 814 are not required.

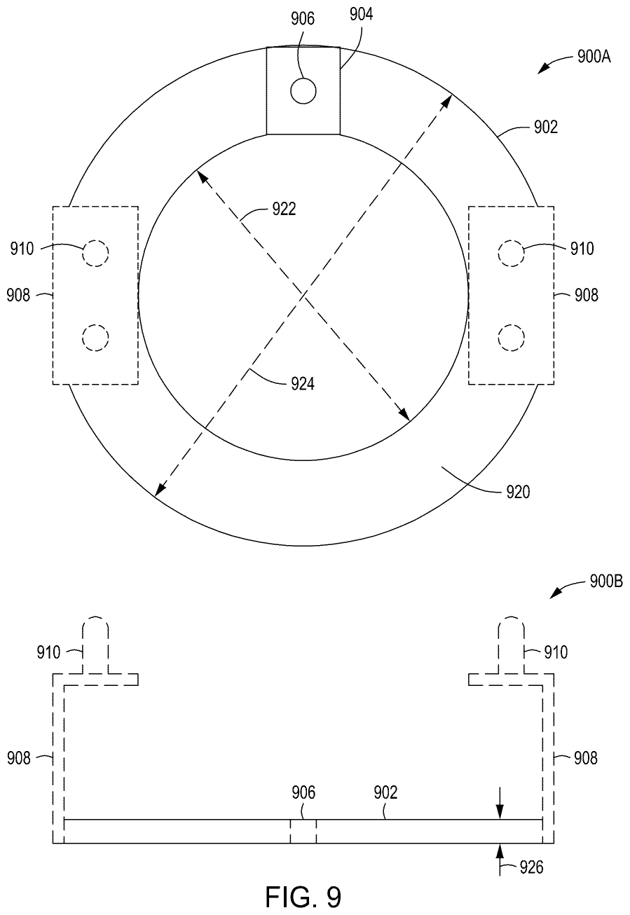

The hoops used in the degas chamber have an annular shape and when more than one hoop is used in the degas chamber, the hoops may have different inner diameters 922, outer diameters 924, and/or thicknesses 926. In FIG. 9, view 900A depicts top-down view of a low emissivity hoop 902 of a degas chamber and view 900B depicts a cross-sectional view of the low emissivity hoop 902 of the degas chamber in accordance with some embodiments. The low emissivity hoop 902 has a mounting or mating area 904 that directly connects with a low emissivity actuator shaft such as a single piece shaft or a two-piece shaft. A connecting component (not shown) may be inserted in the at least one mounting hole 906. The connecting component may be a screw, bolt, or a pin and the like that mates with a recess in the low emissivity actuator shaft (see FIG. 8). If the low emissivity hoop 902 functions as a lifting hoop, a plurality of lifting pin risers 908 may be attached to the low emissivity hoop 902 to increase the vertical height of the lifting pins 910. If the low emissivity hoop 902 functions as a substrate support hoop, the plurality of lifting pin risers 908 and the lifting pins 910 will not be attached to the substrate support hoop as the upper surface 920 provides support for the substrate. In some embodiments, the lifting pin risers 908 and/or the lifting pins 910 may be formed of low emissivity material and/or may be coated or plated on all surfaces or surfaces exposed to the processing volume environment with low emissivity material as provided by the present techniques.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A system for degassing substrates, comprising:
a degas chamber with a microwave source and an infrared temperature sensor positioned in a bottom of the degas chamber;
at least one hoop configured to support or lift a substrate, wherein the at least one hoop has an annular shape and is formed from at least one first material that is opaque to microwaves and has an emissivity of 0.1 or less; and
at least one actuator with a movable vertical shaft, wherein each of the at least one actuator is attached under one of the at least one hoop at an outer perimeter of the one of the at least one hoop, wherein at least a portion of the movable vertical shaft exposed to microwaves from the microwave source in the degas chamber is formed from at least one second material that is opaque to microwaves and has an emissivity of 0.1 or less.

2. The system of claim 1, wherein the at least one first material comprises a first coating applied to the at least one hoop that is opaque to microwaves and has an emissivity of 0.1 or less.

3. The system of claim 2, wherein the first coating is a silver-based material or an aluminum-based material on a core material of stainless steel.

4. The system of claim 1, wherein the at least one second material comprises a second coating applied to at least the portion of the movable vertical shaft exposed to microwaves from the microwave source in the degas chamber and wherein the second coating is opaque to microwaves and has an emissivity of 0.1 or less.

5. The system of claim 4, wherein the second coating is a silver-based material or an aluminum-based material on a core material of stainless steel and wherein the silver-based material or the aluminum-based material has an emissivity of 0.1 or less.

6. The system of claim 1, wherein the movable vertical shaft comprises an upper portion of a third material that is opaque to microwaves and has an emissivity of 0.1 or less and a lower portion of a fourth material.

7. The system of claim 1, wherein the movable vertical shaft is formed from an aluminum-based material that is opaque to microwaves and has an emissivity of 0.1 or less.

8. The system of claim 1, further comprising:
a proportional-integral-derivative (PID) controller in communication with the infrared temperature sensor and the microwave source, wherein the PID controller is configured to control a processing temperature of the substrate based on a reading from the infrared temperature sensor and adjustment of the microwave source.

9. The system of claim 1, wherein one of the at least one hoop is configured to support the substrate during processing in the degas chamber.

10. The system of claim 1, wherein one of the at least one hoop is configured to lift the substrate before and after processing in the degas chamber.

11. An assembly for a degas chamber, comprising:
a movable vertical shaft configured to be installed in the degas chamber, wherein the movable vertical shaft has a bottom end configured to be attached to an actuator and a top end configured to be attached to a hoop that is configured to support or lift a substate, wherein an upper portion of the movable vertical shaft is exposed to an inner environment of the degas chamber when installed in the degas chamber, and wherein the movable vertical shaft is formed from at least one material that is opaque to microwaves and has an emissivity of 0.1 or less.

12. The assembly of claim 11, wherein the at least one material comprises a coating applied to at least the upper portion of the movable vertical shaft which is exposed to inner environment of the degas chamber when the movable vertical shaft is installed in the degas chamber, wherein the coating is opaque to microwaves and has an emissivity of 0.1 or less.

13. The assembly of claim 12, wherein the coating is a silver-based material or an aluminum-based material on a core material of stainless steel and wherein the silver-based material or the aluminum-based material has an emissivity of 0.1 or less.

14. The assembly of claim 11, wherein the movable vertical shaft comprises the upper portion and a lower portion, wherein the upper portion is removable from the lower portion, and wherein the upper portion formed is from material that is opaque to microwaves and has an emissivity of 0.1 or less and the lower portion is formed from stainless steel.

15. The assembly of claim 14, wherein the upper portion and the lower portion are press-fit together, welded together, screwed together, or bolted together.

16. The assembly of claim 11, wherein the movable vertical shaft is formed from an aluminum-based material that is opaque to microwaves and has an emissivity of 0.1 or less.

17. An assembly for a degas chamber, comprising:
a hoop configured to support or lift a substrate in the degas chamber, wherein the hoop has an annular shape with an area configured to attach to a movable shaft connected to an actuator, wherein the hoop is formed from at least one material that is opaque to microwaves and has an emissivity of 0.1 or less.

18. The assembly of claim 17, wherein the at least one material comprises a coating applied to an outer surface of the hoop, wherein the coating is opaque to microwaves and has an emissivity of 0.1 or less.

19. The assembly of claim 18, wherein the coating is a silver-based material or an aluminum-based material on a core material of stainless steel.

20. The assembly of claim 17, wherein the hoop is configured to support a substrate during processing in the degas chamber or is configured to lift the substrate before and after processing in the degas chamber.
